(19) United States
(12) Patent Application Publication
(10) Pub. No.: US 2024/0222320 A1
(43) Pub. Date: Jul. 4, 2024

(54) DIRECTLY BONDED MULTICHIP IC DEVICE PACKAGES

(71) Applicant: Intel Corporation, Santa Clara, CA (US)

(72) Inventors: Suddhasattwa Nad, Chandler, AZ (US); Gang Duan, Chandler, AZ (US); Srinivas Pietambaram, Chandler, AZ (US); Brandon Marin, Gilbert, AZ (US); Jeremy Ecton, Gilbert, AZ (US)

(73) Assignee: Intel Corporation, Santa Clara, CA (US)

(21) Appl. No.: 18/091,265

(22) Filed: Dec. 29, 2022

(51) Int. Cl. H01L 25/065; H01L 21/56; H01L 23/00; H01L 23/31; H01L 23/48; H01L 23/538; H01L 25/00

(52) U.S. Cl. CPC H01L 25/0652; H01L 21/568; H01L 23/3107; H01L 23/481; H01L 23/5381; H01L 23/5383; H01L 24/08; H01L 25/50; H01L 2224/08145

(57) ABSTRACT

Multi-chip/die device including two or more substantially coplanar base IC dies directly bonded to a bridge IC die over or under the base IC dies. Direct bonding of the bridge IC die provides high pitch interconnect. A package metallization routing structure including conductive vias adjacent to the bridge IC die may be built up and terminate at first level interconnect interfaces. A temporary carrier, such as glass, may be employed to form such multi-chip devices.

### BACKGROUND

Monolithic integrated circuit (IC) fabrication has restrictions that may limit a final product's performance, and thus different versions of IC die disaggregation are being investigated. To date however, these techniques and architectures generally suffer from certain drawbacks such as high cost, lower insertion efficiency, and increased z-height.

In electronics manufacturing, IC packaging is a stage of semiconductor device fabrication in which an IC that has been monolithically fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled, for example, into a multi-chip package (MCP).

The electrical interconnection between multiple IC dies is important to ensure device performance is sufficient as die-to-die communication demands can be significantly higher than die-to-host demands. Die-to-die interconnection may be achieved with an embedded die that hosts the interconnect routing. One motivation behind such as solution is that organic dielectric material employed within most packages suffers from high total thickness variation (TTV) and, thus, a large depth of focus (DOF) requirement can limit the resolution of lithography employed to define package metallization features that interconnect two IC die(s).

However, embedding an interconnect bridge die inside a package substrate cavity is challenging. Another difficulty is that die-to-die communication relies heavily on the die bump pitch, which is ultimately limited by the relative bump thickness variation (rBTV) of solder bumps. Current approaches to reduce BTV include the planarization (e.g., CMP) of dielectric build-up material, advanced lamination technologies, bump planarization, and bump plating uniformity improvements. However, these approaches are all expected to significantly reduce factory capacity and increase capital expenditure.

Accordingly, alternative bridge die packaging architectures that can improve electrical performance and reduce bump pitch, enabling more die-to-die connections may be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a multi-chip device structure including multiple IC dies directly bonded to a bridge die and redistribution interconnect layers adjacent to the bridge die, in accordance with some embodiments;

FIG. 2A illustrates a cross-sectional view of a workpiece comprising plurality of IC die affixed to a carrier, in accordance with some embodiments;

FIG. 2B illustrates a plan view of the workpiece illustrated in FIG. 2A, in accordance with some embodiments;

FIG. 3A illustrates a cross-sectional view of a workpiece comprising an IC die directly bonded to at least two IC die affixed to a carrier, in accordance with some embodiments;

FIG. 3B illustrates a plan view of the workpiece illustrated in FIG. 3A, in accordance with some embodiments;

FIG. 4A illustrates a cross-sectional view of a package dielectric and metallization features fabricated upon a workpiece comprising an IC die directly bonded to at least two coplanar IC die affixed to a carrier, in accordance with some embodiments;

FIG. 4B illustrates a plan view of the workpiece illustrated in FIG. 4A, in accordance with some embodiments;

FIG. 5 illustrates a system including a multi-chip device transferred from a carrier and assembled to a host component with FLI features, in accordance with some embodiments;

FIG. 6 illustrates a mobile computing platform and a data server machine employing a multi-chip package, in accordance with some embodiments; and

FIG. 7 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Multi-chip device structures including multiple base IC dies interconnected to each other through a bridge IC die are described herein. Rather than being soldered together, metallization features on a surface of each of the base dies are directly bonded with metallization features of the bridge die. Direct bonding can be facilitated by adhering the base dies to a temporary carrier, which may be glass having a flatness and/or thickness control superior to organic cored/coreless substrates. Direct bonding upon a workpiece comprising adjacent IC dies on such a carrier ensures a low TTV and good dimensional stability.

Package dielectric and metallization features (e.g., comprising a redistribution layer (RDL)) on an opposite side of the carrier may terminate at first level interconnect (FLI) interfaces. Accordingly, packaging dielectric(s) may be applied adjacent to, and over, the bridge die. Patterned metallization features may be embedded within the packaging dielectric(s) to directly form package-to-host (e.g., first level) interconnect interfaces. After building up the package, the carrier may be removed from the multi-chip device. The multi-chip device may be assembled to a device host component (e.g., through first-level interconnect solder features).

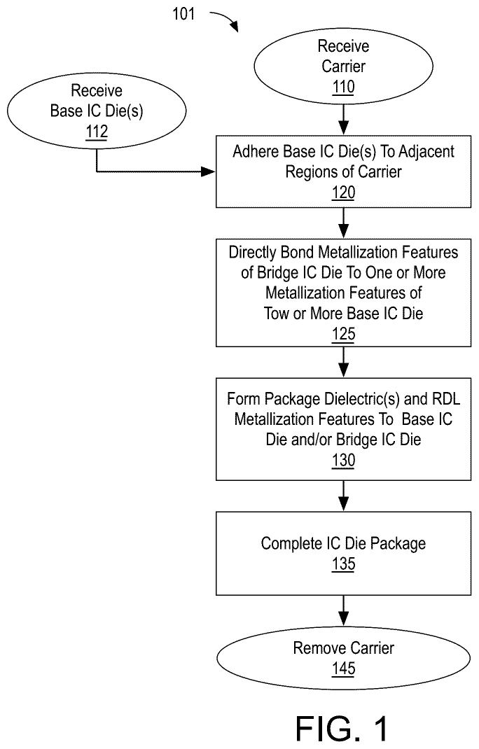

A variety of fabrication methods may be practiced to fabricate multi-chip device structures having one or more of the features or attributes described herein. FIG. 1 illustrates a flow diagram of methods 101 for forming a multi-chip device structure including a directly bonded bridge die and redistribution layer metallization adjacent to the bridge die, in accordance with some embodiments.

Methods 101 begin at input 110 with the receipt of a carrier that has been fabricated upstream of methods 101. In some exemplary embodiments, the carrier comprises at least a glass substrate. The glass substrate ideally has a flatness comparable to that of a silicon wafer, and may be either be the size of a typical silicon wafer (e.g., 350-400 mm) or have larger dimensions (e.g., suitable for large format panel processing), etc. In some examples, the glass substrate is of sufficient thickness to provide mechanical support to a workpiece as one or more multi-chip modules are formed upon the workpiece. Alternatively, the glass substrate may be supported by another handle substrate, such as any of those known to be suitable in the industry.

Methods 101 continue at block 120 where multiple (e.g., two) base IC die(s) received at input 112 are adhered upon a working surface of the carrier. Any temporary adhesive or bond film known to be suitable for die attach (e.g., a thermoset) may be employed to hold an IC die upon a surface of the carrier during subsequent processing of the workpiece. In some examples, at block 120 a pick-and-place machine positions IC dies laterally adjacent to each other upon the temporary adhesive. The adhesive may then be activated and/or cured (e.g., from a b-stage material).

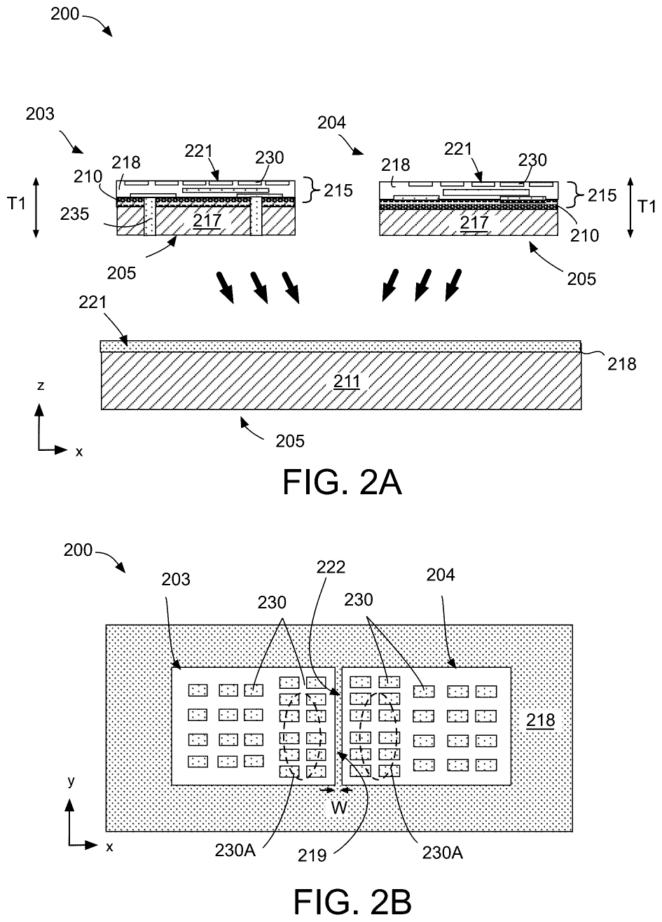

FIG. 2A illustrates a cross-sectional view of a workpiece 200 comprising IC die 203 and IC die 204 being temporarily affixed to a carrier 211. The composition of carrier 211 may vary. In some exemplary embodiments, carrier 211 is a single bulk piece of glass. In other embodiments, carrier 211 comprises one or more thin film material layers on one or both of a front side or back side of a bulk glass substrate. Carrier 211 may therefore be predominantly silica (e.g., silicon and oxygen) and may further include one or more metals, such as, but not limited to aluminum, beryllium, magnesium, calcium, strontium barium, or radium. Additional dopants (e.g., boron, phosphorus) may also be present in carrier 211 (e.g., borosilicate glass, etc.).

Although not depicted, one or more materials may clad either or both of a front side 221 or a back side 205 of carrier 211. Exemplary cladding materials include silicon nitride (SiNₓ) or silicon oxynitride (SiOₓN_{y}). In other embodiments, a silicon layer (polycrystalline or monocrystalline) may clad one or both sides of carrier 211. As further illustrated, an adhesive material layer 218 may be on at least a portion of carrier front side 221. Adhesive material layer 218 may have any composition suitable for a temporary adhesion of IC dies 203, 204 to carrier 211.

As shown in FIG. 2A, IC dies 203, 204 are placed in contact with adhesive material 218 over a planar working surface of carrier 211. A sidewall edge of IC die 203 is laterally adjacent to a sidewall edge of IC die 204. The size of a gap between nearest sidewalls of IC die 203 and 204 may vary, for example according to precision of IC die placement. As a “die-first” method, IC die 203 and 204 are examples of base IC dies that may be interconnected to each other by an interconnect bridge die that is to be subsequently attached to each of them. Although two base dies are illustrated, any number of IC die may be similarly placed laterally adjacent to each other over different regions of carrier 211.

In the example illustrated in FIG. 2A, each IC die 203, 204 has IC layers 215 on a front side surface 221 and further comprises a die substrate material 217 on a back side surface 205. In some examples, IC die substrate material 217 is silicon. In other examples, die substrate material 217 is an alternative crystalline material, such as, but not limited to, germanium, SiₓGe₁₋ₓ, GeₓSn₁₋ₓ or silicon carbide. IC die 203 and IC die 204 may be affixed to carrier 211 “front-side up,” as shown, so that IC layers 215 are distal from carrier 211. In alternative embodiments, IC die 203 and IC die 204 may be flip-chip assembled “front-side down” so that IC layers 215 are instead proximal to carrier 211.

IC die 203 and IC die 204 may each have any architecture. In the illustrated embodiments, each of IC dies 203, 204 is an “active” IC die with one or more types of active devices within a device layer 210. Such active devices may be fabricated into a surface of die substrate material 217, or not (e.g., instead part of a transferred substrate). Device layer 210 may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, device layer 210 includes a Group III-V material comprising a Group III majority constituent and a Group IV majority constituent (e.g., InGaAs, GaAs, GaSb, InGaSb). Device layer 210 may have a thickness of 50-1000 nm, for example. Device layer 210 need not be a continuous material layer, but rather may include active regions of semiconductor material surrounded by field regions of isolation dielectric.

In some embodiments, the active devices within device layer 210 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 10-30 nm. Additionally, or in the alternative, device layer 210 may include active devices other than FETs. For example, device layer 210 may include electronic memory structures, spin valves, or the like.

IC die 203, 204 may comprise one or more IC die metallization levels on either side of device layer 210. In exemplary embodiments, IC layers 215 include die metallization features 230 embedded within an insulator 218. While IC die metallization features 230 may have any composition(s) of sufficient electrical conductivity, in exemplary embodiments, IC die metallization features 230 are predominantly copper (Cu). In other examples, metallization features 230 are predominantly other than Cu, such as, but not limited to predominantly Ru, or predominantly W. An uppermost one of metallization features 230 within IC layers 215 may have a feature pitch ranging from 100 nm to several microns, for example.

IC dies 203 and 204 have substantially the same thickness T1 so that front side surface 221 of the IC 203, 204 is substantially coplanar while back side surface 205 is in contact with adhesive material 218. In the illustrated example, IC die 203 further includes one or more through die substrate vias (TSVs) 235 extending from backside surface 205 through die substrate material 217. Die TSVs 235 couple with IC layers 215, for example contacting one or more metallization features and/or terminals of active or passive devices. die TSVs 235 may have any architecture and generally include a metallization, such as, but not limited to, Cu.

Each of IC dies 203, 204 may be a fully functional ASIC, or may be a chiplet or tile that has more limited functionality supplementing one or more other IC dies that are to be part of the same multi-chip device. A chiplet or tile may, for example, be any of a wireless radio circuit, microprocessor core, electronic memory circuit, floating point gate array (FPGA), power management and/or power supply circuit, or include a MEMS device. In some examples, one or more of IC dies 203, 204 include one or more banks of active repeater circuitry to improve multi-chip interconnects (e.g., network-on-chip architectures). In other examples, one or more of IC dies 203, 204 include clock generator circuitry or temperature sensing circuitry. In other examples, one or more of IC dies 203 or 204 include logic circuitry that implement mesh network-on-chip architectures. In still other examples, at least one of IC dies 203, 204 includes microprocessor core circuitry, for example comprising one or more shift registers. Such microprocessor core circuitry may be part of an intelligence processing unit (IPU), graphical process unit (GPU) or central processing unit, for example. In another embodiments at least one of IC dies 203, 204 is a photonic IC (PIC), for example comprising one or more optical waveguides, optical multiplexer/demultiplexer, lasers and/or photodetectors.

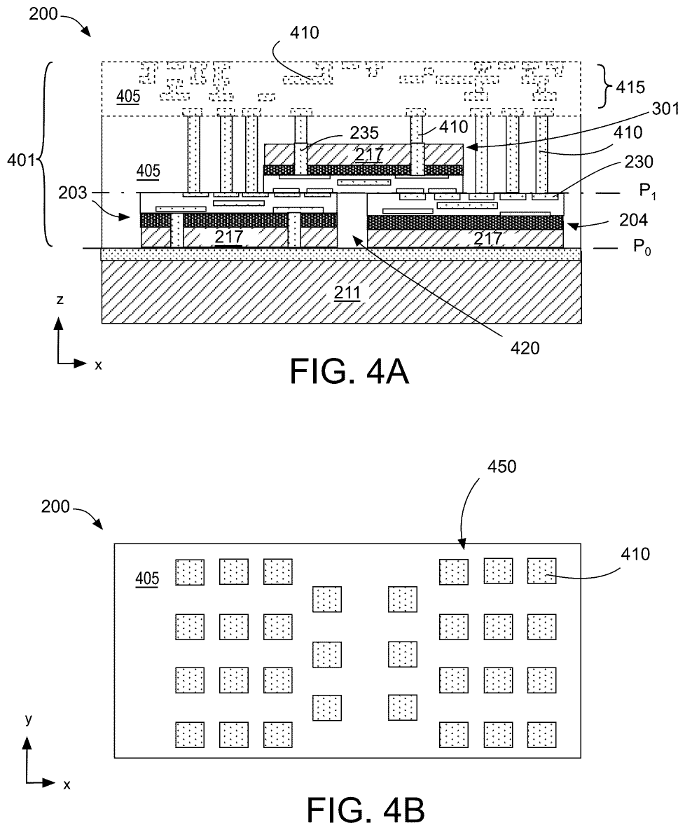

FIG. 2B illustrates a plan view of workpiece 200, in accordance with some embodiments. In this example, carrier 211 (and any excess adhesive material 218) surround each IC die 203, 204, for example forming a perimeter about the edges of each IC die. In the example shown in FIG. 4B, IC dies 203, 204 have been placed with an edge sidewall 219 laterally adjacent to a nearest die edge sidewall 222 with a gap of width W. Gap width W may vary, for example from 100 nm to several microns. As further illustrated, IC die metallization features 230 include at least some subset of features 230A arrayed within the x-y plane at a significantly smaller x and/or y pitch than a remainder of the coplanar metallization features 230.

Returning to FIG. 1, methods 101 continue at block 125 where a bridge IC die is directly bonded to at least some metallization features of two or more of the base die that were affixed to the carrier at block 120. The interconnect bridge die may be directly bonded according to any techniques for die-to-die bonding. In some exemplary embodiments, the bridge die is bonded with a hybrid bonding process to coplanar surfaces of each of multiple adjacent IC dies assembled at block 120. The bridge die bonded at block 125 includes interconnect metallization, for example that has been fabricated with a back-end-of-line (BEOL) monolithic IC die manufacturing process. Accordingly, communications between multiple base die may be, at least in part, conveyed through the bridge IC die bonded at block 125.

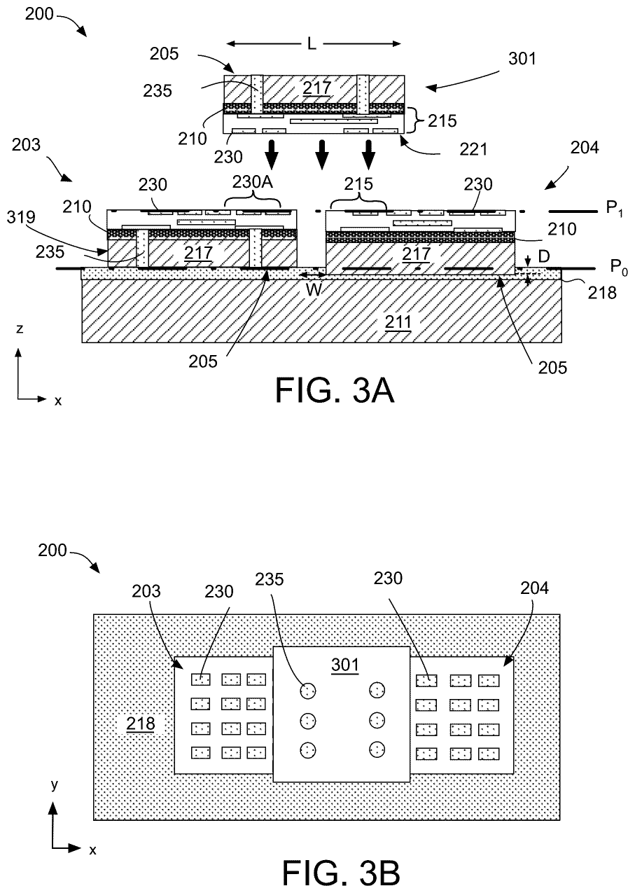

FIG. 3A illustrates a cross-sectional view of workpiece 200 comprising a bridge die 301 directly bonded to at least two base IC die 203, 204. In some exemplary embodiments, bridge die 301 is a “passive” die and lacks any FETs fabricated within device layer 210. Such a passive die may merely include interconnect routing levels within device layers 215. These interconnect routing levels are to convey electrical communication signals between IC dies 203, 204. Alternatively, bridge die 301 may be an “active” die including FETs fabricated within device layer 210. As such, bridge die 301 may comprise any of the circuitry described above for IC dies 203, 204 while further including interconnect routing supporting communication between IC dies 203, 204. For either passive or active embodiments, bridge die 301 may include devices such as resistors, capacitors, or inductors (not depicted).

Bridge die 301 has an edge length L sufficient to overlap a portion of each of IC dies 203, 204. In exemplary embodiments, the edge length L overlaps the metallization features 230A of minimum pitch on each of IC dies 203, 204. Bridge die 301 therefore spans a length L of carrier 211 between at least two laterally adjacent IC dies and the intervening space of width W. Bridge die 301 may only be large enough to overlap a portion of two adjacent IC dies 203 and 204, or may be larger to extend any lateral distance past an opposite edge sidewall 319 of one or more of IC dies 203, 204.

In the illustrated embodiment, bridge die 301 is bonded face-to-face with base IC dies 203, 204. Metallization features 230 within IC layers 215 of bridge die 301 are directly coupled with metallization features 230A within IC layers 215 of at least IC dies 203, 204. While alternative embodiments where bridge die 301 is face-to-back with at least one base IC die (e.g., IC die 203 if flip chip oriented to carrier 211) are also possible, face-to-face bonding may achieve smaller feature pitches than embodiments where metallization features 230 within IC layers 215 of bridge die 301 are directly coupled with TSVs 235 of a base IC die.

As bonded, a metallization feature of bridge die 301 is fused to a metallization feature of the base IC die 203, 204. The resulting composite, quasi-monolithic structure may comprise a hybrid bonded interface of both metallurgically interdiffused metals and chemically bonded dielectric material. As shown in FIG. 3A, hybrid bonding surfaces of IC dies 203, 204 are substantially co-planar and coincident to an x-y plane P₁. This coplanarity of the base IC die may stem from a substantially equal die thickness T1, in which case backside die surfaces 205 will also be coplanar and coincident to x-y plane P₀ at an interface with adhesive material 218. Alternatively, as further illustrated in FIG. 3A, coplanarity along plane P₁ may result from overdriving a thicker one of the base die (e.g., die 204) past plane P₀ and into adhesive material 218 by a distance D. Such overdrive may be dictated by spatial alignment of a bond head during an iterative or concurrent adhesion of IC dies 203, 204 to carrier 211.

As represented by arrows in FIG. 3A, bridge die 301 may be aligned to a target location on each of IC dies 203, 204 with any high-resolution alignment tool, for example of the type found on a chip-level bonding tool commercially available through several industry suppliers. Direct bonding of bridge die 301 to IC dies 203, 204 may sinter metallization features (e.g., via metal interdiffusion) and also bond dielectric materials (e.g., via Si—O—Si condensation bonds). Thermo-compression bonding may be, for example, at low temperature (e.g., below melting temperature of the interconnects, and more specifically below 100° C.). Direct bonding at room temperature (i.e., compression only) may also be suitable. Prior to bonding, any of bridge die 301 or base IC dies 203, 204 may be pre-processed, for example with a plasma clean, to activate their surfaces for the bonding. After bonding, selective heating may be performed to make permanent the bond (e.g., by converting a van der waals bond into a sintered Cu—Cu bond through interdiffusion). For selective heating, a laser may be employed to limit heating to a specific one IC die 203, 204 and/or bridge die 301.

Lateral (e.g., x-axis) misalignment or misregistration between conductive features of bridge die 301 and IC dies 203 and/or 204 may be less than 0.2 μm. However, lateral misalignment between one conductive feature (e.g., a line or trace) and another conductive feature (e.g., a via) within a monolithic IC die may be at least an order of magnitude smaller than the lateral misalignment between bonded conductive features. The lateral dimensions of metallization features at the bond interface are therefore sufficiently large to accommodate lateral offset in a direct bonding process.

FIG. 3B illustrates a plan view of workpiece 200 after bridge die 301 is bonded, in accordance with some embodiments. As shown, bridge die 301 overlaps the subset of metallization features 230A of minimum pitch but does not overlap all metallization features 230. The unbonded die metallization features, along with TSVs 235 exposed on the backside of bridge die 301 may therefore be subsequently coupled to package-level redistribution layer (RDL) metallization features.

Returning to FIG. 1, methods 101 continue at block 130 where one or more package dielectric material layers are formed over the bridged IC die and RDL metallization features are formed. In exemplary embodiments, the RDL metallization features formed at block 130 comprise lateral runs fanning out I/O from the base IC dies and/or bridge IC die and terminating at interconnect interfaces that are to be interconnected with a host of the multi-chip device. The number of layers and/or thicknesses of RDL metallization may vary according to implementation and requirements of the IC dies included within the multi-chip device.

The multi-chip package may then be completed at block 135 where any suitable techniques may be practiced, for example to form interconnect features comprising solder. In accordance with some embodiments, first level interconnects (FLI) may be formed on exposed surfaces of conductive features of the package structures in preparation for packaging or assembly. The multi-chip devices may then be singulated according to any technique. Multi-chip devices may be separated, for example, by kerf or panel frame with each multi-chip device including at least two IC dies that are interconnected to each other through a bridge die directly bonded to a side of the IC dies also coupled to first-level interconnect interfaces.

Once completed, the multi-chip module may then be removed from the carrier at output 145. To remove the IC die, any peeling or lifting process may be practiced. An adhesive decomposition process may also be practiced. For example, UV radiation transmitted through the carrier may decompose a UV-sensitive adhesive to promote separation or delamination of the multi-chip module from the carrier. When the carrier is removed, an additional (e.g., backside) planarization process may be performed on the exposed surface of the base IC dies. The carrier may be cycled through another iteration of methods 101. Alternatively, carrier separation may be delayed until after first-level interconnects of a multi-chip module are coupled to a host component. For such embodiments, the carrier may be diced, or otherwise singulated, as a sacrificial mandrel of methods 101.

FIG. 4A illustrates a cross-sectional view of a package dielectric and metallization features formed on workpiece 200, in accordance with some embodiments. Following bonding, bridge die 301 is encapsulated in a first layer of package dielectric material 405. Package dielectric material 405 may be a dry film laminate, a spin-on build-up material, or a mold material applied around bridge die 301, and over exposed portions of base IC dies 203, 204. Package dielectric 405 may be cast wet/uncured and then dried/cured. Alternatively, package dielectric 405 may be introduced as a semi-cured dry film that is fully cured followings its application to workpiece 200.

In exemplary embodiments, package dielectric mater 405 is an organic material, such as, an epoxy resin, phenolic-glass, or a resinous film such as the GX-series films commercially available from Ajinomoto Fine-Techno Co., Inc. (ABF). Package dielectric material 405 may comprise epoxy resins (e.g., an acrylate of novolac such as epoxy phenol novolacs (EPN) or epoxy cresol novolacs (ECN)). In some specific examples, package dielectric 405 is a bisphenol-A epoxy resin, for example including epichlorohydrin. In other examples, package dielectric material 405 includes bisphenol-F epoxy resin (with epichlorohydrin). In other examples, package dielectric material 405 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package dielectric material 405 includes glycidylamine epoxy resin, such as triglycidyl-p-aminophenol (functionality 3) and N,N,N′,N′-tetraglycidyl-bis-(4-aminophenyl)-methane (functionality 4).

A first level of conductive RDL metallization features 410 are embedded within the first layer of package dielectric 405. Metallization features 410 may be formed, for example, according to an additive or semi-additive process. The first level of metallization features 410 are conductive vias that extend through the first layer of package dielectric 405 (e.g., that is at least as thick as bridge die 301) and contact the die metallization features 230. In some exemplary embodiments, these conductive vias convey signal I/O to/from each of IC dies 203, 204. Notably, the height of via metallization features 410 being at least equal to the total thickness of bridge die 301 is indicative of metallization features 410 having been formed after the bonding of bridge die 301.

In the example shown in FIG. 4A, the first layer of package dielectric 405 is also over bridge die 301 and some of the first level of metallization features 410 contact TSVs 235 of bridge die 301. In some embodiments, these metallization features 410 convey power into bridge die 301 and interconnect routing within bridge die 301 further couples the power to at least one of base IC dies 203, 204. Any technique suitable for the composition of package dielectric material 405 may be employed to form metallization features 410. For embodiments where package dielectric material 405 is photosensitive, a lithographic process may directly pattern package dielectric material 405. Alternatively, a photolithographic masking process may be performed and package dielectric material 405 etched according to the mask. In other embodiments, openings package dielectric material 405 may be ablated, for example with a laser.

In some embodiments, each layer of RDL metallization features 410 is formed by first depositing a seed layer (e.g., Cu) and then forming a plating resist mask (not depicted) over the seed layer. With an electrolytic deposition process, Cu is plated upon the seed layer wherever the resist mask is absent. The building up of RDL metallization features 410 may comprise any number of cycles with each cycle including application of a layer package dielectric material, patterning of the package dielectric, and plating of conductive features within features patterned in package dielectric 405.

As illustrated with dotted line in FIG. 4A, any number of additional layers of package dielectric material 405 may be optionally built up over the first package dielectric material layer to complete a multi-chip device 401. Within each additional dielectric material layer, another level of RDL metallization features 410 may be formed to complete a routing structure 415 over the first level of metallization features 410 that are laterally adjacent to a sidewall of bridge die 301. Routing structure 415 is illustrated in dotted line to emphasize such additional layers are optional and need not be present within multi-chip device 401. Regardless of the number (e.g., 1-8, etc.) of build-up layers, metallization features 410 terminate at interconnect interfaces 450 arrayed over an area of package dielectric material 405, as further shown in FIG. 4B. Interconnect interfaces 450 may be pillars or pads surrounded by a solder resist, for example. Hence, in accordance with the illustrated embodiment, routing structure 415 fan-outs interconnections of the multiple IC dies 203, 204 (and potentially bridge die 301) for further coupling with an external host (not depicted).

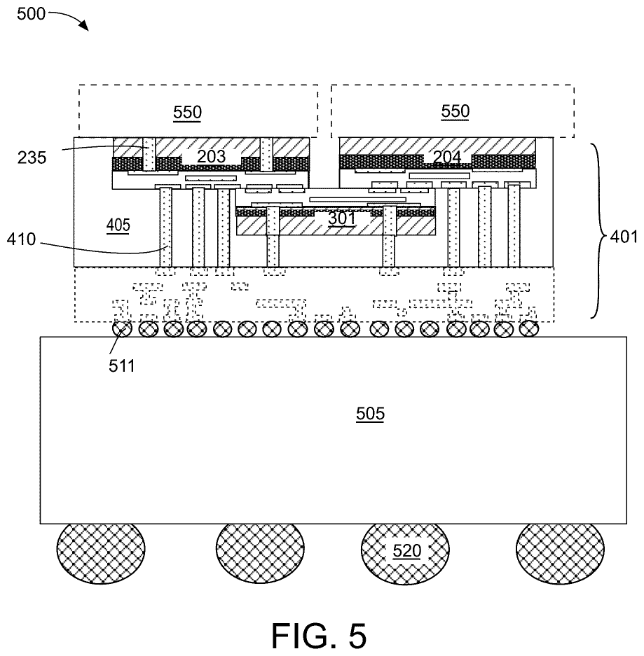

FIG. 5 illustrates a system 500 including multi-chip device 401 assembled to a host component 505 with FLI features 511, in accordance with some embodiments. As shown, multi-chip device 401 has been transferred from the carrier (e.g., 211 in FIG. 4A) and assembled into system 500. In exemplary embodiments, FLI interconnects 511 are solder (e.g., SAC) microbumps although other interconnect features are also possible. Host component 505 may also comprise one or more materials known to be suitable as interposers or package substrates (e.g., an epoxy preform, cored or coreless laminate board, etc.). Host component 505 may include one or more metallized redistribution levels (not depicted) embedded within a dielectric material. Host component 505 may also include one or more IC die embedded therein.

Host component 505 may further include second level interconnects (SLI) 520. SLI 520 may comprise any solder (ball, bump, etc.) suitable for a given host board architecture (e.g., surface mount FR4, etc.). As illustrated in dashed line, one or more heat spreaders and/or heat sinks 550 may be further coupled to multi-chip device 401, which may be advantageous, for example, where IC dies 203, 204 comprise one or more CPU cores or other circuitry of similar power density.

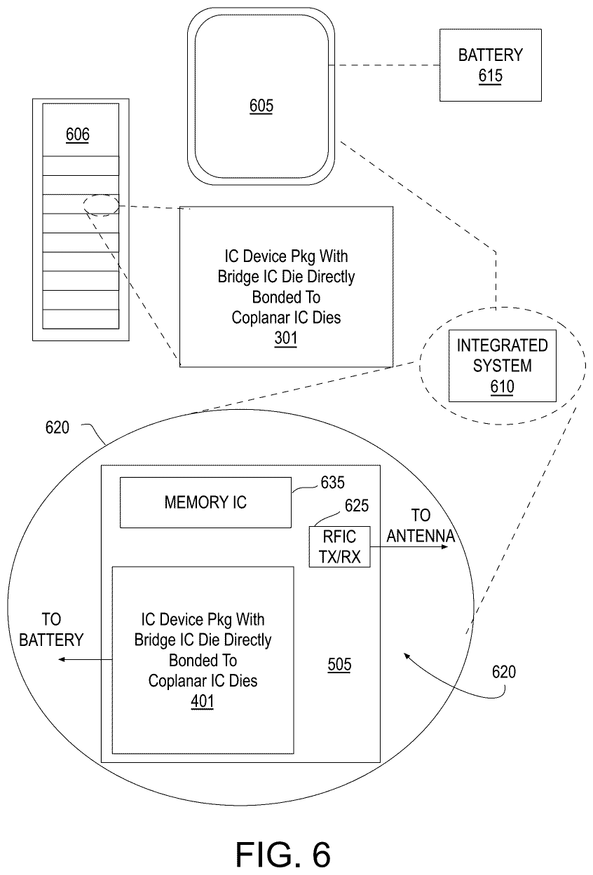

FIG. 6 illustrates a mobile computing platform 605 and a data server machine 606 employing a multi-chip IC device with coplanar IC die interconnected by, and directly bonded to, a bridge die and redistribution layer metallization features on the same side, for example as described elsewhere herein. Server machine 606 may be any commercial server, for example including any number of high-performance computing platforms disposed within a rack and networked together for electronic data processing, which in the exemplary embodiment includes multichip device 401, for example as described elsewhere herein. The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), an integrated system 610, and a battery 615.

As illustrated in the expanded view, multi-chip device 401 is coupled to one or more of a power management integrated circuit (PMIC) or RF (wireless) integrated circuit (RFIC) including a wideband RF (wireless) transmitter and/or receiver. A PMIC may perform battery power regulation, DC-to-DC conversion, etc., and so has an input coupled to battery 615 and with an output providing a current supply to other functional modules. As further illustrated, in the exemplary embodiment, an RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

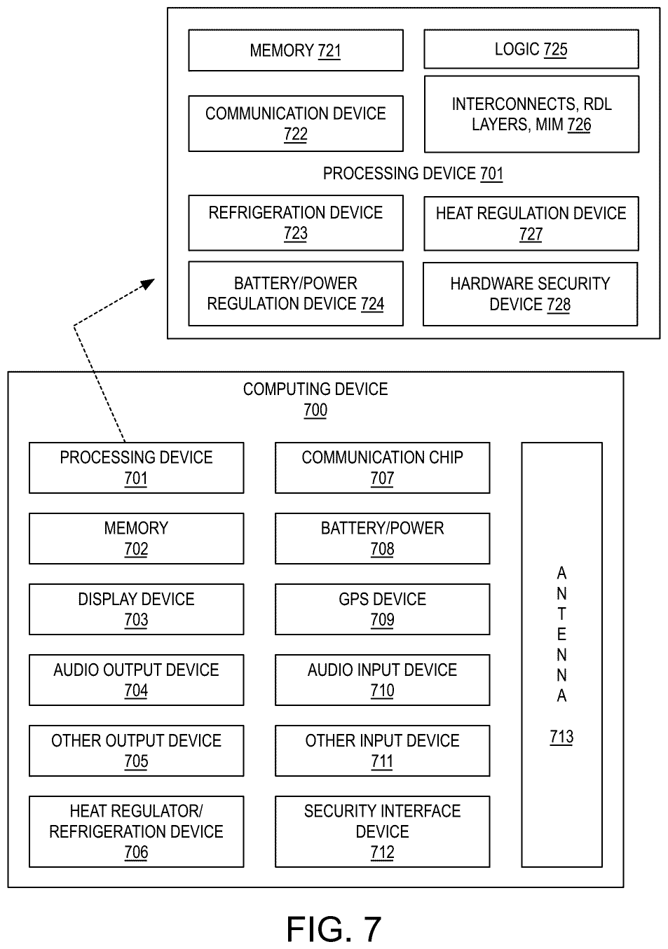

FIG. 7 is a block diagram of a cryogenically cooled computing device 700 in accordance with some embodiments. For example, one or more components of computing device 700 may include any of the devices or structures discussed elsewhere herein. A number of components are illustrated in FIG. 7 as included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled.

Computing device 700 may include a processing device 701 (e.g., one or more processing devices). As used herein, the term processing device or processor indicates a device that processes electronic data from registers and/or memory to transform that electronic data into other electronic data that may be stored in registers and/or memory. Processing device 701 may include a memory 721, a communication device 722, a refrigeration/active cooling device 723, a battery/power regulation device 724, logic 725, interconnects 726, a heat regulation device 727, and a hardware security device 728.

Processing device 701 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 701 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 721 includes memory that shares a die with processing device 702. This memory may be used as cache memory and may include embedded dynamic random-access memory (eDRAM) or spin transfer torque magnetic random-access memory (STT-M RAM).

Computing device 700 may include a heat regulation/refrigeration device 706. Heat regulation/refrigeration device 706 may maintain processing device 702 (and/or other components of computing device 700) at a predetermined low temperature during operation. This predetermined low temperature may be any temperature discussed elsewhere herein.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium.

Communication chip 707 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a global positioning system (GPS) device 709 (or corresponding interface circuitry, as discussed above). GPS device 709 may be in communication with a satellite-based system and may receive a location of computing device 700, as known in the art.

Computing device 700 may include another output device 705 (or corresponding interface circuitry, as discussed above). Examples include an audio codec, a video codec, a printer, a wired or wireless transmitter for providing information to other devices, or an additional storage device.

Computing device 700 may include another input device 711 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, managing access lists, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an integrated circuit (IC) device comprises a first IC die comprising first metallization features on a first side of the first IC die and a second IC die laterally adjacent to the first IC die. The second IC die comprises second metallization features on a first side of the second IC die. The IC device further comprises a third IC die stacked over the first and second IC die and comprising third metallization features on a first side of the third IC die. The third metallization features are in direct contact with a first number of each of the first and second metallization features. The IC device comprises a package dielectric material adjacent to the third IC die and over the first side of each of the first and second IC dies, and a routing structure within the package dielectric material. The routing structure comprises fourth metallization features in contact with a second number of each of the first and second metallization features. The routing structure terminates at first-level interconnect interfaces.

In second examples, for any of the first examples the third metallization features electrically interconnect the first IC die to the second IC die.

In third examples, for any of the first through second examples a second side of the first IC dies comprises a crystalline first die substrate, the second side of the second IC comprises a crystalline second die substrate. A surface of the first substrate is substantially coplanar with a surface of the second substrate. A thickness of the first IC die is substantially equal to a thickness of the second IC die.

In fourth examples, for any of the first through third examples the package dielectric material has a first thickness at least equal to a second thickness of the third IC die. The fourth metallization features comprise vias extending through an entirety of the first thickness of the package dielectric material.

In fifth examples, for any of the fourth examples a second side of the third IC die comprises a crystalline die substrate. The third IC die comprises a through substrate via (TSV) extending through the die substrate. The TSV is coupled to the third metallization features. The package dielectric has a second thickness over a second side of the third IC die. The fourth metallization features comprise a via in contact with the TSV.

In sixth examples, for any of the fourth examples the fourth metallization features comprise redistribution lines embedded within a layer of the package dielectric material, the redistribution lines in contact with, and fanning out from, the vias.

In seventh examples, for any of the first through sixth examples the third metallization features comprise a plurality of features directly bonded to the first number of first and second metallization features at a bond interface that is coincident with a plane passing through an interface of the fourth metallization features and the second number of first and second metallization features.

In eighth examples, for any of the first through seventh examples each of the first and second IC dies further comprises a device layer over a crystalline die substrate on a second side of first and second IC dies, and the third IC die is a passive die lacking any transistors within a device layer.

In ninth examples, for any of the first through eighth examples the fourth metallization features comprise predominantly Cu and the package dielectric comprises an organic polymer dielectric material surrounding the fourth metallization features.

In tenth examples, for any of the ninth examples, the organic polymer dielectric material comprises at least one of epoxy, polyimide, or ABF.

In eleventh examples, for any of the first through tenth examples the package dielectric material is absent from between a first sidewall of the first IC die facing a second sidewall of the second IC die.

In twelfth examples, a system comprises a plurality of laterally adjacent IC dies and an interconnect bridge die on a first side of the adjacent IC dies. The system comprises an interconnect bridge die comprising metallization features directly bonded to metallization features within a first region of each of the plurality of laterally adjacent IC die. The system comprises a package dielectric material over the interconnect bridge die and over second regions of each of the plurality of laterally adjacent IC die. The system comprises a routing structure embedded within the package dielectric material, the routing structure comprising metallization features in contact with a second number of metallization features within a second region of each of the plurality of laterally adjacent IC die and terminating at first-level interconnect interfaces. The system comprises a host component interconnected to the first routing structure through first-level interconnects coupled to the first-level interconnect features.

In thirteenth examples, for any of the twelfth examples the first-level interconnect features comprise solder.

In fourteenth examples, for any of the twelfth through thirteenth examples the system comprises a power supply coupled through the host component to provide power to the plurality of adjacent IC dies.

In fifteenth examples, for any of the fourteenth examples the interconnect bridge die comprises a plurality of through substrate vias (TSVs) coupled to the metallization features within the first region of each of the plurality of laterally adjacent IC de, and the power supply is coupled to the plurality of adjacent IC dies through the TSVs.

In sixteenth examples, a method of assembling an integrated circuit (IC) device comprises adhering a first IC die and a second IC die adjacent to each other on a glass substrate. The method comprises attaching a third IC die to a first number of metallization features on a first side of the first and second IC dies, the third IC die spanning a portion of the glass substrate between the first and second IC dies. The method comprises building up second metallization features within a package dielectric material adjacent to the third IC die and contacting a second number of the metallization features on the first side of the first and second IC dies, the second metallization features terminating at first level interconnect interfaces. The method comprises removing the glass substrate after building up the second metallization features to expose a second side of the first IC die and the second IC die.

In seventeenth examples, for any of the sixteenth examples the method comprises attaching the third IC die further comprises directly bonding a first portion of the third IC die to a first portion of the first IC die concurrently with directly bonding a second portion of the third IC die to a first portion of the second IC die.

In eighteenth examples, for any of the sixteenth through seventeenth examples building up the second metallization features within the package dielectric material comprises applying an organic material over a second portion of the first IC die concurrently with a second portion of the second IC die and curing the organic material.

In nineteenth examples, for any of the eighteenth examples building up the second metallization features within the package dielectric material comprises planarizing the package dielectric material over a top surface of the third IC die.

In twentieth examples, for any of the eighteenth through nineteenth examples building up the second metallization features within the package dielectric material comprises forming first vias through the package dielectric material and in contact with the second number of metallization features on the first side of the first IC die and the second IC die.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
a first IC die comprising first metallization features on a first side of the first IC die;
a second IC die laterally adjacent to the first IC die, wherein the second IC die comprises second metallization features on a first side of the second IC die;
a third IC die stacked over the first and second IC die and comprising third metallization features in direct contact with a first number of each of the first and second metallization features;
a package dielectric material adjacent to the third IC die and over the first side of each of the first and second IC dies;
a routing structure within the package dielectric material, the routing structure comprising fourth metallization features in contact with a second number of each of the first and second metallization features, and terminating at first-level interconnect interfaces.

2. The apparatus of claim 1, wherein the third metallization features electrically interconnect the first IC die to the second IC die.

3. The apparatus of claim 1, wherein:
a second side of the first IC dies comprises a crystalline first die substrate;
the second side of the second IC comprises a crystalline second die substrate;
a surface of the first substrate is substantially coplanar with a surface of the second substrate; and
a thickness of the first IC die is substantially equal to a thickness of the second IC die.

4. The apparatus of claim 1, wherein the package dielectric material has a first thickness at least equal to a second thickness of the third IC die, and wherein the fourth metallization features comprise vias extending through an entirety of the first thickness of the package dielectric material.

5. The apparatus of claim 4, wherein:
a second side of the third IC die comprises a crystalline die substrate;
the third IC die comprises a through substrate via (TSV) extending through the die substrate;
the TSV is coupled to the third metallization features;
the package dielectric has a second thickness over a second side of the third IC die; and
the fourth metallization features comprise a via in contact with the TSV.

6. The apparatus of claim 4, wherein the fourth metallization features comprise redistribution lines embedded within a layer of the package dielectric material, the redistribution lines in contact with, and fanning out from, the vias.

7. The apparatus of claim 1, wherein the third metallization features comprise a plurality of features directly bonded to the first number of first and second metallization features at a bond interface that is coincident with a plane passing through an interface of the fourth metallization features and the second number of first and second metallization features.

8. The apparatus of claim 1, wherein:
each of the first and second IC dies further comprises a device layer over a crystalline die substrate on a second side of first and second IC dies; and
the third IC die is a passive die lacking any transistors within a device layer.

9. The apparatus of claim 1, wherein the fourth metallization features comprise predominantly Cu and the package dielectric comprises an organic polymer dielectric material surrounding the fourth metallization features.

10. The apparatus of claim 9, wherein the polymer dielectric material comprises at least one of epoxy, polyimide, or ABF.

11. The apparatus of claim 1, wherein the package dielectric material is absent from between a first sidewall of the first IC die facing a second sidewall of the second IC die.

12. A system comprising:
a plurality of laterally adjacent IC dies;
an interconnect bridge die on a first side of the adjacent IC dies, the interconnect bridge die comprising metallization features directly bonded to metallization features within a first region of each of the plurality of laterally adjacent IC die;
a package dielectric material over the interconnect bridge die and over second regions of each of the plurality of laterally adjacent IC die;
a routing structure embedded within the package dielectric material, the routing structure comprising metallization features in contact with a second number of metallization features within a second region of each of the plurality of laterally adjacent IC die and terminating at first-level interconnect interfaces; and
a host component interconnected to the first routing structure through first-level interconnects coupled to the first-level interconnect features.

13. The system of claim 12, wherein the first-level interconnect features comprise solder.

14. The system of claim 13, further comprising a power supply coupled through the host component to provide power to the plurality of adjacent IC dies.

15. The system of claim 14, wherein:
the interconnect bridge die comprises a plurality of through substrate vias (TSVs) coupled to the metallization features within the first region of each of the plurality of laterally adjacent IC de; and
the power supply is coupled to the plurality of adjacent IC dies through the TSVs.

16. A method, comprising:
adhering a first IC die and a second IC die adjacent to each other on a glass substrate;
attaching a third IC die to a first number of metallization features on a first side of the first and second IC dies, the third IC die spanning a portion of the glass substrate between the first and second IC dies;
building up second metallization features within a package dielectric material adjacent to the third IC die and contacting a second number of the metallization features on the first side of the first and second IC dies, the second metallization features terminating at first level interconnect interfaces; and
removing the glass substrate after building up the second metallization features to expose a second side of the first IC die and the second IC die.

17. The method of claim 16, wherein attaching the third IC die further comprises directly bonding a first portion of the third IC die to a first portion of the first IC die concurrently with directly bonding a second portion of the third IC die to a first portion of the second IC die.

18. The method of claim 16, wherein building up the second metallization features within the package dielectric material comprises applying an organic material over a second portion of the first IC die concurrently with a second portion of the second IC die and curing the organic material.

19. The method of claim 18, wherein building up the second metallization features within the package dielectric material comprises planarizing the package dielectric material over a top surface of the third IC die.

20. The method of claim 18, wherein building up the second metallization features within the package dielectric material comprises forming first vias through the package dielectric material and in contact with the second number of metallization features on the first side of the first IC die and the second IC die.
